(19) United States
(12) Patent Application Publication
(10) Pub. No.: US 2019/0310548 A1
(43) Pub. Date: Oct. 10, 2019

(54) NANOPRINTING DEVICE, MATERIALS AND METHOD

(71) Applicant: NanoPath, Inc., Leominster, MA (US)

(72) Inventor: Kevin Donahue, Harvard, MA (US)

(73) Assignee: NanoPath, Inc., Leominster, MA (US)

(21) Appl. No.: 16/374,512

(22) Filed: Apr. 3, 2019

Related U.S. Application Data
(60) Provisional application No. 62/652,689, filed on Apr. 4, 2018.

(51) Int. Cl. G03F 7/00

(52) U.S. Cl. CPC G03F 7/0002

(57) ABSTRACT

A device for nano-assembly of nanoparticles in nanoimprinted wells on a substrate surface includes a substrate holder, a platen, a heater and a conveyor. The substrate holder is arranged to support the substrate. The platen is arranged to have a print gap between the substrate and platen, the print gap containing a nanoink having a carrier fluid and nanoparticles within the carrier fluid. The heater is configured to provide heat to the substrate holder. The conveyor is configured to move the substrate relative to the platen such that nanoparticles are nanoassembled into the nanoimprinted wells as the substrate traverses a carrier fluid filled nano-assembly area by motion of the substrate holder.

### RELATED APPLICATIONS

This application claims priority to U.S. Provisional Application Ser. No. 62/652,689 filed Apr. 4, 2018, entitled “NANOPRINTING DEVICE, MATERIALS AND METHOD,” incorporated by reference herein in its entirety.

### FIELD OF DISCLOSURE

The present disclosure is directed to systems and methods for the rapid deposition of nanoparticles within nanoimprinted wells.

### BACKGROUND

Nanoparticles have been shown to “nano-assemble” or “self-assemble” into a structured material without the application of significant heat or pressure. The phenomenon occurs because nanoparticles lack the size to exhibit the random, or Brownian, motion commonly associated with the presence of particles within a fluid. Instead nanoparticles, due to their size, can avoid interaction with fluid molecules enabling them to subsequently bind to each other to form solid structures, thus avoiding the traditional steps associated with forming a solid part, including for example a melt-cure cycle to thermoforming a part.

To date, evaporative, or convective, nano-assembly has been demonstrated, wherein nanoparticles, suspended in water, nano-assemble as they are deposited into nanoimprinted wells upon being dragged across a nanoimprinted surface. The mass transfer process associated with this deposition is slow and involves the establishment of an air-nanoink-substrate interface within a printing channel (formed by a platen parallel to the nanoimprinted substrate) that concentrates nanoparticles in a deposition wave that ultimately causes the nanoparticles to selectively drop into each nanoimprinted well.

### SUMMARY

According to inventive concepts disclosed herein, there is provided a device for nano-assembly of nanoparticles in nanoimprinted wells on a substrate surface. The device comprises a substrate holder, a platen, a heater and a conveyor. The substrate holder is arranged to support the substrate. The platen is arranged to have a print gap between the substrate and platen, the print gap containing a nanoink having a carrier fluid and nanoparticles within the carrier fluid. The heater is configured to provide heat to the substrate holder. The conveyor is configured to move the substrate relative to the platen such that nanoparticles are nanoassembled into the nanoimprinted wells as the substrate traverses a carrier fluid filled nano-assembly area by motion of the substrate holder.

According to inventive concepts disclosed herein, the carrier fluid is water.

According to inventive concepts disclosed herein, the nanoparticles have a diameter less than 500 nanometers.

According to inventive concepts disclosed herein, a width of the nanoimprinted wells is less than 10 microns.

According to inventive concepts disclosed herein, the substrate is glass.

According to inventive concepts disclosed herein, the substrate is a plastic.

According to inventive concepts disclosed herein, the plastic comprises at least one of Polyethylene Terephthalate Glycol (PETG), Polycarbonate (PC), Polymethylmetharcylate (PMMA) or Polystyrene (PS).

According to inventive concepts disclosed herein, the nanoparticles include a nanoparticle core, and a nanoparticle coating which coats the nanoparticle core, wherein the coating is of a material that matches the surface energy of the nanoimprinted substrate.

According to inventive concepts disclosed herein, the nanoparticle core comprises a metal or a metal oxide.

According to inventive concepts disclosed herein, the nanoparticle core comprises a metal or a metal oxide, and the coating is of a material with a surface energy matching or similar to the surface energy of the nanoimprinted substrate.

According to inventive concepts disclosed herein, the conveyor is a vibration-free rail driven by air compression or a mechanical drive.

According to inventive concepts disclosed herein, a distance of the print gap is equal to a meniscus height of a drop of the carrier fluid upon the platen.

According to inventive concepts disclosed herein, the platen comprises at least one of Teflon, Delrin, or acetal.

According to inventive concepts disclosed herein, a surface of the platen which contacts the carrier fluid is polished.

According to inventive concepts disclosed herein, the nanoparticles have a surface energy near a surface energy of the nanoimprinted substrate and lower than a surface energy of the carrier fluid.

According to inventive concepts disclosed herein, a difference in surface energy between the nanoparticles and the nanoimprinted substrate is less than 5 mN/m.

According to inventive concepts disclosed herein, the difference in surface energy between the nanoparticles and the carrier fluid is greater than 25 mN/m.

According to inventive concepts disclosed herein, there is provided a method of nanoprinting on a nanoimprinted substrate having a plurality of nanoimprinted wells. A nanoink is introduced into a print gap between the nanoimprinted substrate and a platen, the nanoink having a carrier fluid and nanoparticles within the carrier fluid. The nanoimprinted substrate is moved relative to the platen to transport the nanoparticles in the carrier fluid across the nanoimprinted substrate such that the nanoparticles are nanoassembled into the nanoimprinted wells, the nanoparticles having a surface energy near a surface energy of the nanoimprinted substrate.

According to inventive concepts disclosed herein, the method further comprises controlling the temperature of the nanoimprinted substrate to be within a 90-125° F. range.

According to inventive concepts disclosed herein, after the nanoparticles are nanoassembled into the nanoimprinted wells, mechanically wiping away remaining nanoparticles present on a top surface of the nanoimprinted substrate, followed by exposing the top surface to a water rinse.

### BRIEF DESCRIPTION OF THE DRAWINGS

Implementations of the inventive concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 is a side view of a nanoimprinted substrate according to inventive concepts disclosed herein.

FIG. 2 is a side view of a device for nano-assembly of nanoparticles in nanoimprinted wells on a substrate surface according to inventive concepts disclosed herein.

FIG. 3 is a side view illustrating the nanoimprinted substrate with assembled nanoparticles according to inventive concepts disclosed herein.

FIG. 4 illustrates a nanoparticle comprising a nanoparticle core and coating according to inventive concepts disclosed herein.

FIG. 5 is a side view of a display including assembled nanoparticles according to inventive concepts disclosed herein.

### DETAILED DESCRIPTION

According to embodiments of the inventive concepts disclosed, there is provided a nanoprinting device and method for the rapid deposition of nanoparticles within nanoimprinted wells by establishing a surface energy gradient, between a carrier fluid, for example water, nanoparticles, and a nanoimprinted substrate, within an evaporative environment, that causes the carrier fluid to be rapidly displaced by the nano-assembly of nanoparticles within each well of the nanoimprinted substrate. Beneficially, this nanoprinting device and method provides for low cost nano-printing that can be executed in wide format to impart numerous effects, including illumination, transparent illumination, electronics, signal processing, structural color, and numerous other nanoscale devices.

According to embodiments of the inventive concepts disclosed herein, the nanoprinting device and corresponding printing method include may nanoink, a nanoimprinted substrate, and a platen. The nanoink may comprise a suspension of coated nanoparticles within deionized (DI) water. The nanoimprinted substrate may be an optical plastic, such as Polyethylene Terephthalate Glycol (PETG), with a surface that has been nanoimprinted with micro or nanoscale wells. The nanoprinter applies nanoink to the nanoimprinted substrate by creating an environment that enables the nanoparticles, suspended within the nanoink, to be rapidly deposited into the nanoimprinted wells.

While not being bound to a particular theory, a mechanism for the rapid nano-assembly of the nanoparticles appears to include the relative surface energy. According to the Marangoni Effect, low surface energy materials rapidly displace higher surface energy materials causing rapid movement of any particles present in the higher surface energy material. Typically, with larger particles, this surface energy gradient between materials would transport the particles away within the higher surface energy material. For example, if micron-scale particles, like finely ground pepper particles, were applied to the surface of water, when a surfactant such as a detergent was applied to the water surface, the micron-scale particles would be transported away by the rapid movement of the water away from the lower-energy surface established by the detergent.

According to embodiments of the inventive concepts disclosed herein, instead of rapid particle displacement, i.e. movement away from the nanoimprinted wells of the nanoimprinted substrate, nanoparticles coated with a low surface energy coating have instead exhibited near instantaneous deposition into the nanoimprinted wells. Due to the small size of the coated nanoparticles, the low surface energy of the nanoparticles within the nano-ink (including nanoparticles and carrier fluid) in combination with a low surface energy of the nanoimprinted substrate, cause a surface energy gradient between the nanoimprinted substrate and the carrier fluid, and between the coated nanoparticles and the carrier fluid, which facilitates rapid nano-assembly of nanoparticles within the nanoimprinted wells of the of the nanoimprinted substrate.

Examples of exemplary parameters and surface energies of the nanoparticles, carrier fluid and nanoimprinted substrate follow. For example, when the surfaces of both the nanoparticles and nanoimprinted substrate surface are in the 40 mN/m range, while water remains in the 70 mN/m range, a nano-ink filled printing gap between the platen and the nanoimprinted substrate of about 0.5 mm can employed so as to cause the rapid nano-assembly of nanoparticles within the nanoimprinted wells on the nanoimprinted substrate surface. Print conditions that enable nano-assembly may use a nanoink and nanoimprinted substrate temperature range of 90-125° F., for example. Further, the nanoimprinted substrate may remain vibration-free for movement across the nanoink filled print gap (the nano-printing area) which is arranged between the low surface energy platen and the nanoimprinted substrate.

Regarding the nanoparticles within the above described nanoinks including nanoparticles and water as a carrier fluid, it was demonstrated repeatedly that the surface energy of nanoparticles, including metal oxide and metal particles, could be manipulated by applying a coating. For example titania particles of 50-150 nm in diameter were very rapidly deposited into 2 micron wide nanoimprinted wells after being coated with approximately 30 nm of Polyethylene Glycol (PEG), which has a relatively low surface energy, where such coating may be provided, for example, by nanoComposix of San Diego, Calif. Further, such coatings may be optical coating providing channels for light manipulation upon nano-assembly. For example, uncoated titania particles appeared to form a dielectric mirror when nano-assembled, whereas PEG-coated titania produced significant light scattering.

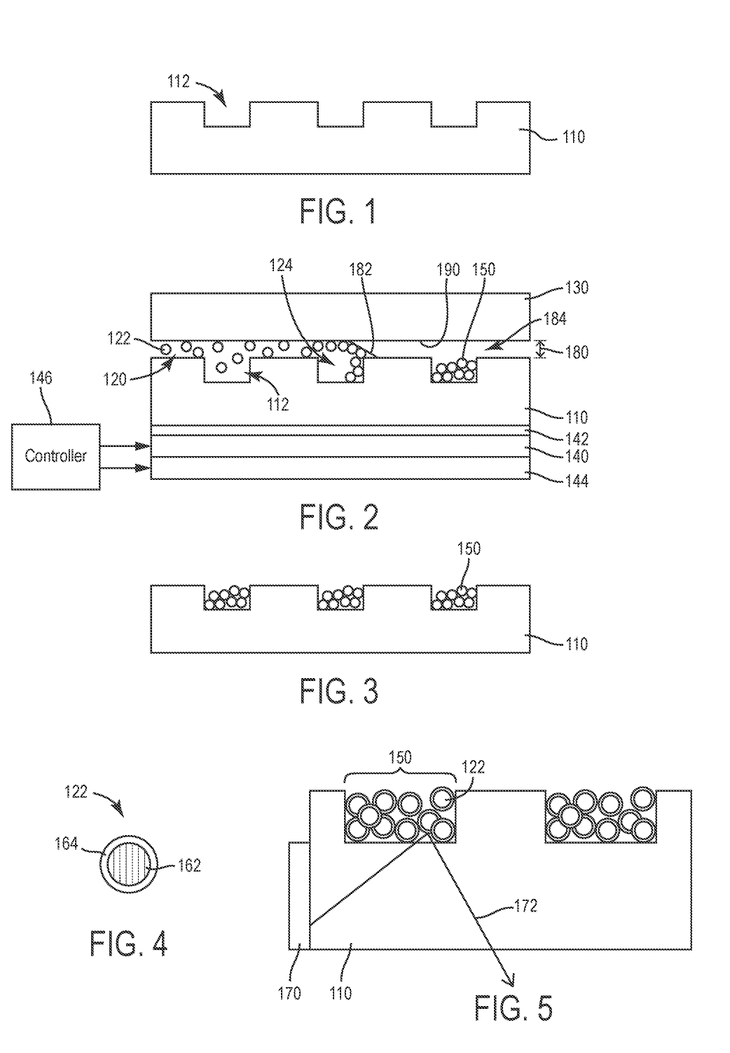

FIG. 1 is a side view of a nanoimprinted substrate 110 according to the inventive concepts disclosed herein. The nanoimprinted substrate 110 includes a plurality of nanoimprinted wells 112 formed in a surface of the nanoimprinted substrate 110. The nanoimprinted substrate 110 may comprise a transparent plastic or glass material, for example. The plastic may be, for example, at least one of Polyethylene Terephthalate Glycol (PETG), Polycarbonate (PC), Polymethylmethacrylate (PMMA) or Polystyrene (PS). The nanoimprinted wells 112 may be less than 10 microns, and may be 0.5 microns to 10 um wide, for example. A width of the nanoimprinted wells 112 may be less than 10 microns, for example. The nanoimprinted wells 112 may be 0.5 microns to 5 microns deep, for example. The wells 112 may be rendered by nanoimprinting. Such nanoimprinting may be provided by a number of vendors, such as by Luminit of Pasadena, Calif. or Zinniatek of New Zealand, among others.

FIG. 2 is a side view of a device for nano-assembly of nanoparticles in nanoimprinted wells on a substrate surface. The device includes a substrate support 142, a platen 130, a heater 140 and a conveyor 144. The substrate support 142 is arranged to support the nanoimprinted substrate 110.

The platen 130 is arranged to have a print gap 180 between a top surface 192 of the substrate 110 and a bottom surface 190 of the platen 130. The top surface 192 of the substrate 110 and the bottom surface 190 of the platen 130 may be parallel to each other such that the print gap 180 remains constant. The platen 130 may comprise a material of at least one of Teflon, Delrin, or acetal, for example, and should have a relatively low surface energy.

The print gap 180 contains a nanoink 120 having a carrier fluid 124, such as water, and nanoparticles 122 within the carrier fluid 124. The nanoparticles 122 may have a diameter less than 500 nanometers, for example. The bottom surface 190 of the platen 130 may be polished where it contacts the nanoink 120.

A distance of the print gap 180 is equal to the meniscus height of a drop of the carrier fluid 124 upon the platen 130. Thus, the print gap 180 has a height that is near-equivalent to the meniscus height of the nanoink 120 as determined by the placement of a droplet of the nanoink 120 on the top surface 192 of the nanoimprinted substrate 110.

Both the heater 140 and a conveyor 144 are controlled by controller 146. The heater 140 is configured to provide heat to the substrate support 142, the specific temperature of the substrate 110 controlled by the controller 146. The conveyor 144 is configured to move the substrate 110 relative to the platen 130 such that nanoparticles 122 are nanoassembled into the nanoimprinted wells 112 as the substrate 110 traverses a carrier fluid 124 filled nano-assembly area by motion of the substrate support 142. The conveyor 144 may be a vibration-free rail driven by air compression or a mechanical drive, for example.

The device of FIG. 2 in operation provides a method of nanoprinting on the nanoimprinted substrate 110 nanoimprinted wells 112. The nanoink 120 is introduced into the print gap 180 between the nanoimprinted substrate 110 and the platen 130. The nanoimprinted substrate 110 is moved relative to the platen 130 to transport the nanoparticles 122 in the carrier fluid 124 across the nanoimprinted substrate 110 such that the nanoparticles 122 are nanoassembled into the nanoimprinted wells 112. The nanoparticles 122 have a surface energy near a surface energy of the nanoimprinted substrate 120, and the nanoparticles 122 and the nanoimprinted substrate 120 have a surface energy lower than that of the carrier fluid 124 to facilitate the rapid movement of the nanoparticles 122 into the nanoimprinted wells 112. The difference in surface energy between the nanoparticles 122 and the nanoimprinted substrate 120 may be less than 5 mN/m, for example. The difference in surface energy between the nanoparticles 122 and the carrier fluid may be greater than 25 mN/m, for example.

To facilitate optimal nano-assembly the nanoimprinted substrate 110 is heated by the heater 140. Heat should be uniform and may be in the 90-125° F. range, for example. The controller 146 may control the temperature of the nanoimprinted substrate 110 to be within the 90-125° F. range.

The nano-printing process begins when the nano-printed substrate 110 is dragged forward by the conveyor 144. This dragging motion causes an interface 182 of air 184, carrier liquid 124 and nanoimprinted 110 substrate causes the nanoparticles 122 to nano-assemble within each nanoimprinted well 112.

FIG. 3 is a side view illustrating the nanoimprinted substrate 110 with assembled nanoparticles 150. After the nanoparticles are nanoassembled into the nanoimprinted wells 122, remaining nanoparticles 122 present on the top surface 192 of the nanoimprinted substrate 110 may be mechanically wiped away, followed by exposing the top surface 192 to a water rinse. FIG. 4 depicts a nanoparticle 122 comprising a nanoparticle core 162 and a nanoparticle coating 164 on the nanoparticle core 162. The coating 164 may be made of an optical material that promotes light manipulation, such as filtration or diffusion of light. Further, to facilitate rapid nano-assembly by establishing a surface energy gradient, the coating 164 may be made of a material with a surface energy that is lower than the carrier liquid 124, such as water, while also near-matching the surface energy of the nanoimprinted substrate 110. An example of a compounded nanoparticle that diffuses light upon nano-assembly is titania core nanoparticles coated with PEG. The nanoparticle core 162 may comprise a metal or a metal oxide. The nanoparticle core 162 may comprise a metal or a metal oxide, and the coating 164 may be of a material with a surface energy matching or similar to the surface energy of the nanoimprinted substrate 110.

FIG. 5 is a side view illustrating a display including the assembled nanoparticles 150 according to the inventive concepts disclosed herein. The display of FIG. 5 includes the nanoprinted substrate 110 with nanoimprinted wells 112 that have been filled by the assembled nanoparticles 150. The nanoparticles 122 of the assembled nanoparticles 150 may comprise a nanoparticle core 162 and a nanoparticle coating 164, for example as shown in FIG. 4. The display of FIG. 5 may include a light source 150, such as an LED, which injects light into the nanoprinted substrate 110. The light ray 172 from the light source 170 may interact with assembled nanoparticles 150 to reflect or diffuse the light ray 172.

Embodiments of the inventive concepts disclosed herein with the disclosed formation conditions provide a low-cost printing device to facilitate nano-printing across a large surface area resulting in a final material with semiconductor-scale features without the need for a clean room, or the purchase of expensive capital equipment normally associated with consistent nanoscale deposition of metals, metal oxides, and other materials. According to the inventive concepts disclosed herein the nanoprinting device may be run at high yield to provide consistent deposition across a wide area in normal room conditions to provide 2 micron-wide, or smaller, nanoimprinted wells. It is believed these excellent yields may result because potential contaminants, like dust particles, are much larger than the nanoimprinted wells and do not appear to provide a binding surface for the nanoparticles.

Embodiments of the inventive concepts disclosed herein provide for the rapid deposition of nanoparticles into nanoimprinted wells to form new metamaterials capable of performing, for example, electronic or light-manipulative functions. Since the formation method may include a single step for forming nanoparticles in nano-impressions, the process may be fast and high yielding. The nanoprinting device and method need not require expensive reagents or inputs, can be practiced under “standard” environmental conditions using inexpensive capital equipment, and may produce novel metamaterials at a very low manufacturing cost.

The embodiments of the inventive concepts disclosed herein have been described in detail with particular reference to preferred embodiments thereof, but it will be understood by those skilled in the art that variations and modifications can be effected within the spirit and scope of the inventive concepts.

Embodiments of the inventive concepts disclosed herein have been described with reference to drawings. The drawings illustrate certain details of specific embodiments that implement systems and methods of the present disclosure. However, describing the embodiments with drawings should not be construed as imposing any limitations that may be present in the drawings.

The foregoing description of embodiments has been presented for the purposes of illustration and description. It is not intended to be exhaustive or to limit the subject matter to the precise form disclosed, and modifications and variations are possible in light of the above teachings or may be acquired from practice of the subject matter disclosed herein. The embodiments were chosen and described in order to explain the principals of the disclosed subject matter and its practical application to enable one skilled in the art to utilize the disclosed subject matter in various embodiments with various modification as are suited to the particular use contemplated. Other substitutions, modifications, changes and omissions may be made in the design, operating conditions and arrangement of the embodiments without departing from the scope of the presently disclosed subject matter.

### The Following is an Enumeration of Reference Labels with Elements

110 nanoimprinted substrate
112 nanoimprinted well
120 nanoink
122 nanoparticle
124 carrier fluid
130 platen
140 heater
142 substrate support
144 conveyor
146 controller
150 assembled nanoparticles
162 nanoparticle core
164 nanoparticle coating
170 light source
172 light ray
180 print gap
182 air-nanoink interface
184 air
190 platen bottom surface
192 nanoimprinted substrate top surface

What is claimed is:

1. A device for nano-assembly of nanoparticles in nanoimprinted wells on a substrate surface, comprising:
a substrate holder arranged to support the substrate;
a platen arranged to have a print gap between the substrate and platen, the print gap containing a nanoink having a carrier fluid and nanoparticles within the carrier fluid;
a heater configured to provide heat to the substrate holder; and
a conveyor configured to move the substrate relative to the platen such that nanoparticles are nanoassembled into the nanoimprinted wells as the substrate traverses a carrier fluid filled nano-assembly area by motion of the substrate holder.

2. The device of claim 1, wherein the carrier fluid is water.

3. The device of claim 1, wherein the nanoparticles have a diameter less than 500 nanometers.

4. The device of claim 1, wherein a width of the nanoimprinted wells is less than 10 microns.

5. The device of claim 1, wherein the substrate is glass.

6. The device of claim 1, wherein the substrate is a plastic.

7. The device of claim 6, wherein the plastic comprises at least one of Polyethylene Terephthalate Glycol (PETG), Polycarbonate (PC), Polymethylmethacrylate (PMMA) or Polystyrene (PS).

8. The device of claim 1, wherein the nanoparticles include a nanoparticle core, and a nanoparticle coating which coats the nanoparticle core, wherein the coating is of a material that matches the surface energy of the nanoimprinted substrate.

9. The device of claim 8, wherein the nanoparticle core comprises a metal or a metal oxide.

10. The device of claim 8, wherein the nanoparticle core comprises a metal or a metal oxide, and the coating is of a material with a surface energy matching or similar to the surface energy of the nanoimprinted substrate.

11. The device of claim 1, wherein the conveyor is a vibration-free rail driven by air compression or a mechanical drive.

12. The device of claim 1, wherein a distance of the print gap is equal to a meniscus height of a drop of the carrier fluid upon the platen.

13. The device of claim 1, wherein the platen comprises at least one of Teflon, Delrin, or acetal.

14. The device of claim 1, wherein a surface of the platen which contacts the carrier fluid is polished.

15. The device of claim 1, wherein the nanoparticles have a surface energy near a surface energy of the nanoimprinted substrate and lower than a surface energy of the carrier fluid.

16. The device of claim 15, wherein the difference in surface energy between the nanoparticles and the nanoimprinted substrate is less than 5 mN/m.

17. The device of claim 15, wherein the difference in surface energy between the nanoparticles and the carrier fluid is greater than 25 mN/m.

18. A method of nanoprinting on a nanoimprinted substrate having a plurality of nanoimprinted wells, comprising:
introducing a nanoink into a print gap between the nanoimprinted substrate and a platen, the nanoink having a carrier fluid and nanoparticles within the carrier fluid; and
moving the nanoimprinted substrate relative to the platen to transport the nanoparticles in the carrier fluid across the nanoimprinted substrate such that the nanoparticles are nanoassembled into the nanoimprinted wells, the nanoparticles having a surface energy near a surface energy of the nanoimprinted substrate.

19. The method of claim 18, further comprising controlling the temperature of the nanoimprinted substrate to be within a 90-125° F. range.

20. The method of claim 18, wherein, after the nanoparticles are nanoassembled into the nanoimprinted wells, mechanically wiping away remaining nanoparticles present on a top surface of the nanoimprinted substrate, followed by exposing the top surface to a water rinse.
